(19) United States
(12) Patent Application Publication
(10) Pub. No.: US 2004/0017873 A1
(43) Pub. Date: Jan. 29, 2004

(54) Analog delay locked loop characterization technique

(76) Inventors: Kian Chong, Sunnyvale, CA (US); Dean Liu, Sunnyvale, CA (US); Claude Gauthier, Fremont, CA (US)

Correspondence Address: ROSENTHAL & OSHA L.L.P. / SUN, 1221 MCKINNEY, SUITE 2800, HOUSTON, TX, 77010, US

(21) Appl. No.: 10/205,373

(22) Filed: Jul. 25, 2002

(51) Int. Cl. H03D 3/24

(52) U.S. Cl. 375/376; 375/224

(57) ABSTRACT

A delay locked loop characterization technique for automatically characterizing a delay locked loop is provided. The technique tests the delay locked loop using a top-down approach in order to ensure the robustness of the delay locked loop. Top-level testing involves testing the performance of the delay locked loop in different process corners, and the results obtained from the top-level testing are then used to test sub-components of the delay locked loop.

### BACKGROUND OF INVENTION

As shown in FIG. 1, a typical computer system 10 has, among other components, a microprocessor 12, one or more forms of memory 14, integrated circuits 16 having specific functionalities, and peripheral computer resources (not shown), e.g., monitor, keyboard, software programs, etc. These components communicate with one another via communication paths 19, e.g., wires, buses, etc., to accomplish the various tasks of the computer system 10.

In order to properly accomplish such tasks, the computer system 10 relies on the basis of time to coordinate its various operations. To that end, a crystal oscillator 18 generates a system clock signal (referred to and known in the art as “reference clock” and shown in FIG. 1 as SYS_CLK) to various parts of the computer system 10. Modem microprocessors and other integrated circuits, however, are typically capable of operating at frequencies significantly higher than the system clock, and thus, it becomes important to ensure that operations involving the microprocessor 12 and the other components of the computer system 10 use a proper and accurate reference of time.

Accordingly, as the frequencies of modern computers continue to increase, the need to rapidly transmit data between circuit interfaces also increases. To accurately receive data, a clock signal is often transmitted to help recover data transmitted to a receiving circuit by some transmitting circuit. The clock signal determines when the data should be sampled by the receiving circuit. In some cases, the clock signal may change state at the beginning of the time the data is valid. However, this is typically undesirable because the receiving circuit operates better when the clock signal is detected during the middle of the time the data is valid. In other cases, the clock signal may degrade as it propagates from its transmission point. Such degradation may result from process, voltage, and/or temperature variations that directly or indirectly affect the clock signal. To guard against the adverse effects of poor and inaccurate clock signal transmission, a delay locked loop (“DLL”) is commonly used to generate a copy of the clock signal at a fixed phase shift with respect to the original clock signal.

FIG. 2 shows a portion of a typical computer system in which a DLL 30 is used. In FIG. 2, data 32 is transmitted from a transmitting circuit 34 to a receiving circuit 36. To aid in the recovery of the data 32 by the receiving circuit 36, a clock signal 38 is transmitted along with the data 32. To ensure that the data 32 is properly latched by the receiving circuit 36, the DLL 30 (which in FIG. 2 is shown as being part of the receiving circuit 36) regenerates the clock signal 38 to a valid voltage level and creates a phase shifted version of the clock signal 38. Accordingly, the use of the DLL 30 in this fashion ensures (1) that the data 32 is properly latched by triggering the receiving circuit 36 at a point in time in which the data 32 is valid and (2) that the clock signal 38 is buffered by the receiving circuit 36.

FIG. 3 shows a typical DLL 40. A reference clock signal, ref_clk 42, serves as an input to a phase detector 44 and a voltage-controlled delay line 46 that has a plurality of delay elements 48. An output clock signal, out_clk 50, from the voltage-controlled delay line 46 serves as an output of the DLL 40 and as a second input to the phase detector 44. The phase detector 44 compares the phase offsets between the reference clock 42 and the output clock 50 and, in turn, generates pulses on UP and DOWN signals 52 and 54 to a charge pump 56. Depending on the UP and DOWN signals 52 and 54, the charge pump 56 adds or removes charge from a filter capacitor 58 using a control voltage signal Vctrl 60. The control voltage signal 60 is then used by a bias generator 62 to produce bias voltages Vcp and Vcn 64 and 66 that control the delay of the delay elements 48 in the voltage-controlled delay line 46. Thus, the DLL 40 is used to maintain a fixed phase relationship between its input clock signal and its output clock signal.

As mentioned above, as the need for and proliferation of DLLs continues to increase with increasing processor speeds, DLL accuracy and functionality is becoming a significant and important concern for circuit designers and the like.

### SUMMARY OF INVENTION

According to one aspect of the present invention, a method for characterizing a delay locked loop comprises top-level testing the delay locked loop to generate a waveform representative of an operation of the delay locked loop, and bottom-level testing a circuit in the delay locked loop dependent on the waveform.

According to another aspect, a computer-readable medium has recorded therein instructions executable by processing for top-level testing a delay locked loop to generate a waveform representative of an operation of the delay locked loop, and bottom-level testing a circuit in the delay locked loop dependent on the waveform.

According to another aspect, a computer system comprises: a processor; a memory; and instructions, residing in the memory and executable by the processor, for top-level testing a delay locked loop to generate a waveform representative of an operation of the delay locked loop, and bottom-level testing a circuit in the delay locked loop dependent on the waveform.

According to another aspect, a method for characterizing a delay locked loop comprises a step for top-level testing the delay locked loop to generate a waveform representative of an operation of the delay locked loop, and a step for bottom-level testing a circuit in the delay locked loop dependent on the waveform.

Other aspects and advantages of the invention will be apparent from the following description and the appended claims.

### BRIEF DESCRIPTION OF DRAWINGS

FIG. 1 shows a typical computer system.

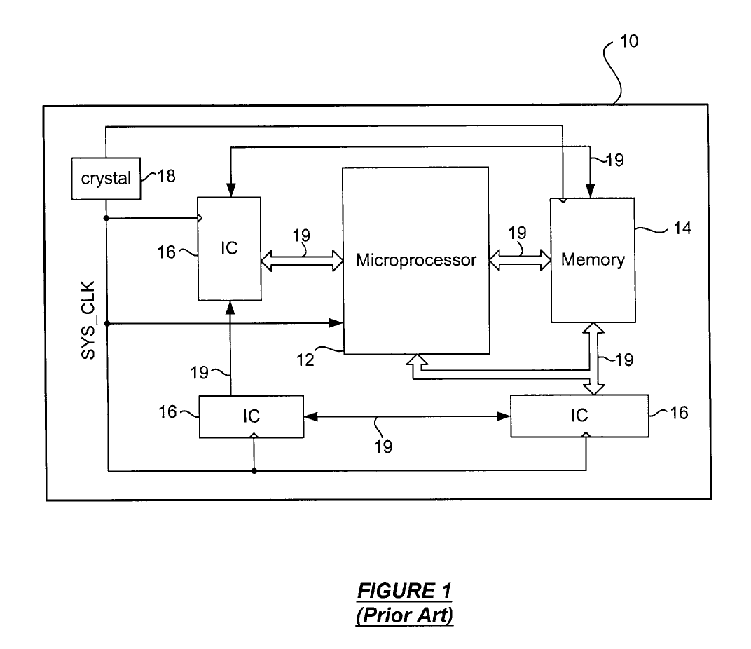

FIG. 2 shows a portion of a typical computer system in which a DLL is used.

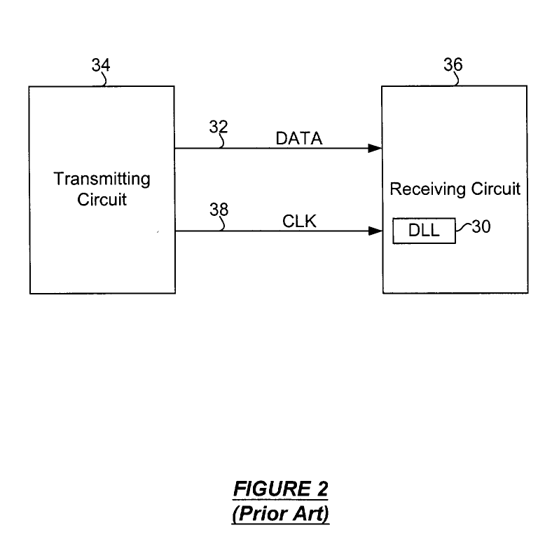

FIG. 3 shows a typical DLL.

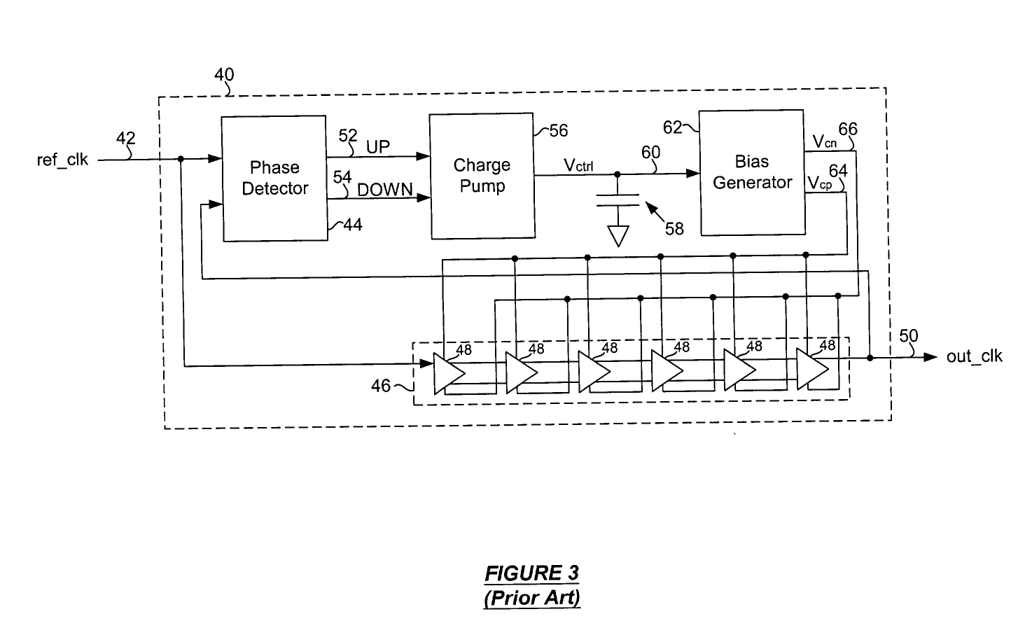

FIG. 4 shows a block diagram in accordance with an embodiment of the present invention.

FIG. 5 shows a flow process in accordance with an embodiment of the present invention.

FIG. 6 shows a flow process in accordance with an embodiment of the present invention.

FIG. 7 shows a computer system in accordance with an embodiment of the present invention.

### DETAILED DESCRIPTION

Embodiments of the present invention relate to a technique for characterizing the behavior of a DLL. Embodiments of the present invention further relate to a computer system that uses a characterization engine to test and simulate a DLL. Embodiments of the present invention further relate to a software tool for characterizing a DLL.

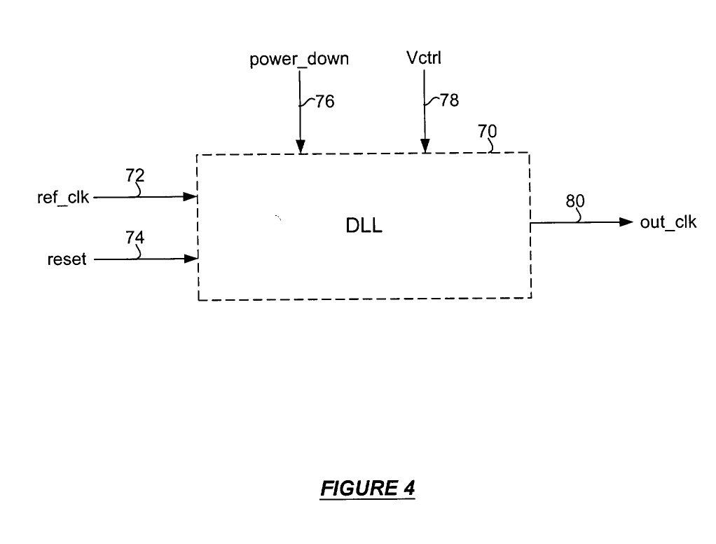

FIG. 4 shows a block diagram of a DLL 70 used to describe an embodiment of the present invention. A DLL characterization tool selectively adjusts values of signals associated with the DLL 70, such as an input reference clock, ref_clk 72, a reset signal, reset 74, a power down signal, power_down 76, a control voltage, Vctrl 78, and output clock, out_clk 80. The DLL characterization tool controls the simulation of the DLL 70 by providing various values for these signal at a wide range of process corners. The DLL characterization tool tests the DLL 70 exhaustively by using a top-down approach to ensure the robustness of the DLL 70. In other words, the DLL characterization tool initially tests the DLL 70 from a perspective of components outside the DLL 70 and then tests the DLL 70 from a perspective of components inside the DLL 70. Using this approach, the DLL characterization tool is able to determine waveforms and other behavior of the DLL 70 from a high-level perspective and then apply the determined waveforms to components within the DLL 70.

The top-level testing involves one or more of the following: adjusting a phase of the reference clock 72, adjusting a frequency of the reference clock 72, adjusting a duty cycle of the reference clock 72, and adjusting relationships of differential inputs to the DLL 70. The bottom-level testing tests the DLL's 70 components thoroughly in order to provide detailed insight of the performance levels of the components individually.

For operation, the DLL characterization tool inputs a circuit schematic of the DLL 70 and a configuration file that includes a description of the inputs, outputs, and other signals of interest of the DLL 70 as shown in FIG. 4. Using this information, the DLL characterization tool simulates the DLL 70 and runs transient analysis techniques to simulate the locking behavior of the DLL 70. Results of the simulation may then be read by the DLL characterization tool and put into a desirable format, e.g., chart, plot, table, etc.

Those skilled in the art will appreciate that such a DLL characterization tool is especially useful for analog DLLs because such DLLs can operate in many different states. Thus, a DLL characterization tool as described above with reference to FIG. 4 is able to automate an analog DLL in many simulated process corners.

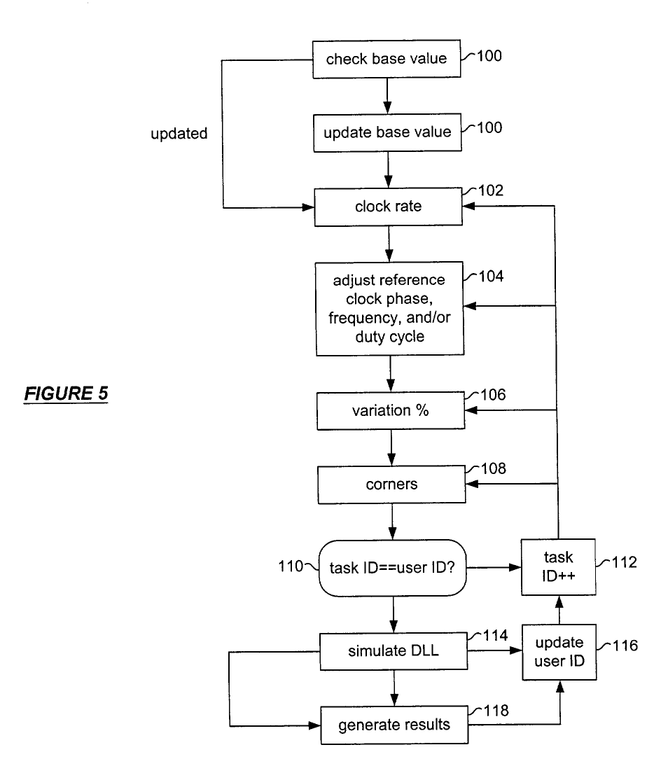

FIG. 5 shows an exemplary flow process in accordance with an embodiment of the present invention. Particularly, FIG. 5 shows a flow process of a top-level characterization of a DLL. The top-level characterization updates base values that are used to determine the starting point and measuring point for data collection when the DLL is locked 100. Based on user or system desires, the top-level characterization involves examining and/or adjusting the input clock rate 102, phase and frequency of the reference clock 104, the duty cycle of the reference clock 104. Further, to consider circuit variations, a variation percentage may be examined/adjusted 106. Various process corners are then considered 108. When a task ID meets a user's selected task ID 110, the task ID is incremented 112 and the top-level characterization generates a spice deck and launches a simulator that simulates the DLL 114. Thereupon, the task ID is updated 116 and results are generated in a desired format 118.

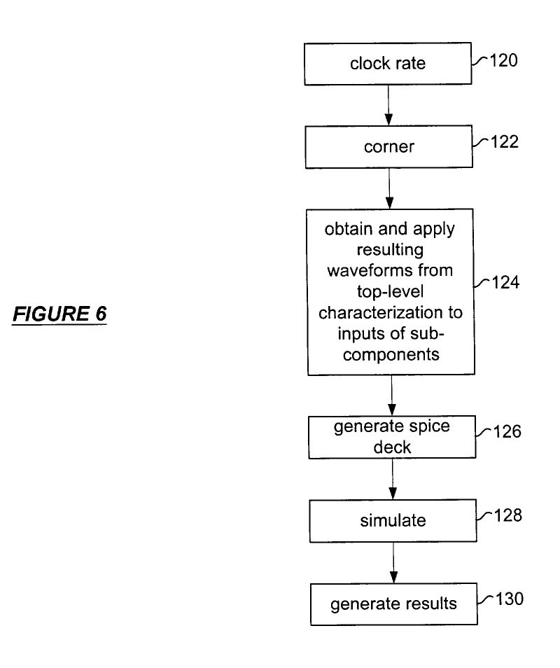

FIG. 6 shows an exemplary flow process in accordance with an embodiment of the present invention. Particularly, FIG. 6 shows a flow process of a bottom-level characterization of a DLL. During the bottom-level characterization, the rate of the reference clock is clocked 120, and a process corner for the bottom-level characterization is determined 122. Thereupon, resulting waveforms from the top-level characterization are obtained and applied to inputs of components within the DLL 124. Thereafter, a spice deck is generated 126 and the components within the DLL are simulated 128. Afterwards, results from the bottom-level characterization may be generated 130.

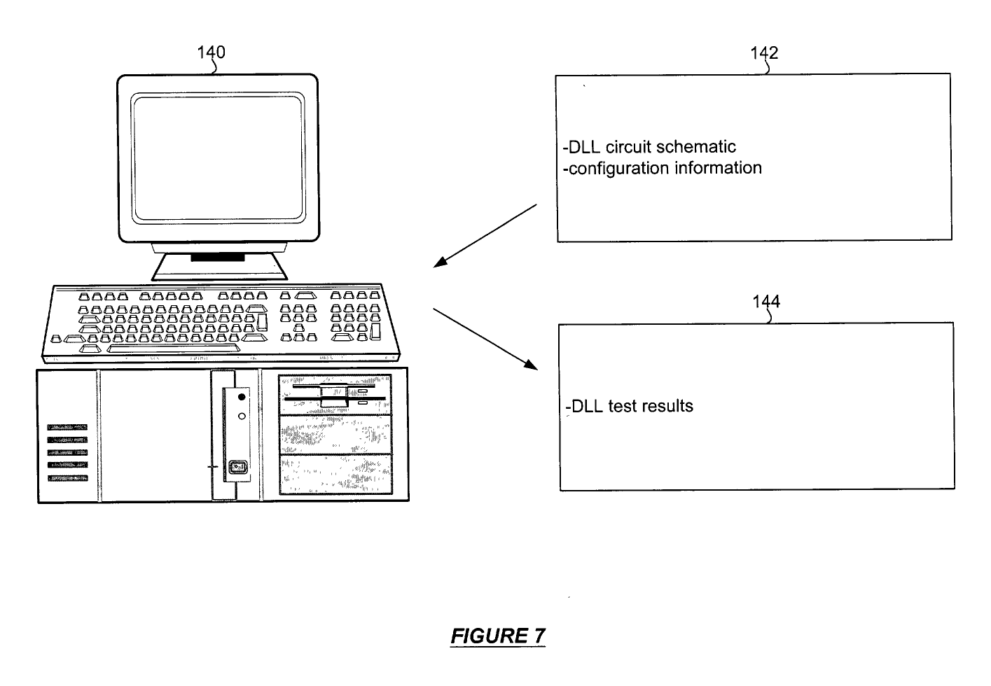

FIG. 7 shows an exemplary computer system 140 that automatically characterizes an analog DLL in accordance with an embodiment of the present invention. Input parameters 142 provided to the computer system 140 include a circuit schematic and configuration information descriptive of particular signals associated with the DLL. The input parameters 142 serve as input data to the computer system 140 via some computer-readable medium, e.g., network path, floppy disk, input file, keyboard, etc. The computer system 140 then permanently or temporarily stores the input parameters 142 in memory (not shown) to subsequently test (via processor functions) the DLL in a plurality of simulation process corners in accordance with one of the various techniques discussed with reference to the present invention.

Thereafter, depending on a chip designer's request, the computer system 140 outputs DLL test results 144 via some user-readable medium, e.g., monitor display, network path, etc., where the results 144 may include information indicating the simulated behavior of the DLL in a plurality of process corners.

Those skilled in the art will appreciate that in other embodiments, a software program capable of characterizing an analog DLL may be used. Those skilled in the art will further appreciate that embodiments of the present invention may also relate to an integrated circuit manufacturing process by which a integrated designer designs for manufacture an integrated circuit having an analog DLL designed using one of the DLL characterization techniques presented by means of describing the present invention.

Advantages of the present invention may include one or more of the following. In some embodiments, because a DLL characterization tool is capable of testing an analog DLL in a plurality of process corners and under various circumstances, subsequent DLL performance may be improved.

In some embodiments, because a top-down approach is used to characterize a DLL, the approach may extract resulting waveforms and use them as input waveforms for sub-circuits within the DLL. This is advantageous because the input waveforms reflect the actual signals that are coming in from the devices that are driving it. This allows designers to have a more realistic view of the performance levels of components within the DLL.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A method for characterizing a delay locked loop, comprising:
top-level testing the delay locked loop to generate a waveform representative of an operation of the delay locked loop; and
bottom-level testing a circuit in the delay locked loop dependent on the waveform.

2. The method of claim 1, wherein the top-level testing comprises:
inputting a circuit schematic of the delay locked loop;
inputting configuration information descriptive of at least one signal associated with the delay locked loop; and
simulating the delay locked loop in at least one process corner using the circuit schematic and configuration information.

3. The method of claim 1, wherein the top-level testing comprises at least one selected from the group consisting adjusting a phase of an input to the delay locked loop, adjusting a frequency of the input to the delay locked loop, and adjusting a duty cycle of the input to the delay locked loop.

4. The method of claim 1, wherein the top-level testing is performed at a plurality of process corners.

5. The method of claim 1, further comprising:
analyzing the circuit by applying the waveform to an input of the circuit.

6. The method of claim 1, wherein the top-level testing comprises:
applying a test value to one selected from the group consisting a reference clock input to the delay locked loop, a reset signal to the delay locked loop, a control voltage of the delay locked loop, a power signal to the delay locked loop, and an output clock of the delay locked loop; and
storing the waveform, wherein the waveform is determined based on the applying.

7. A computer-readable medium having recorded therein instructions executable by processing, the instructions for:
top-level testing a delay locked loop to generate a waveform representative of an operation of the delay locked loop; and
bottom-level testing a circuit in the delay locked loop dependent on the waveform.

8. The method of claim 7, wherein the instructions for the top-level testing comprise instructions for at least one selected from the group consisting adjusting a phase of an input to the delay locked loop, adjusting a frequency of the input to the delay locked loop, and adjusting a duty cycle of the input to the delay locked loop.

9. The method of claim 7, wherein the top-level testing is performed at a plurality of process corners.

10. The method of claim 7, wherein the instructions for the top-level testing comprise instructions for:
applying a test value to one selected from the group consisting a reference clock input to the delay locked loop, a reset signal to the delay locked loop, a control voltage of the delay locked loop, a power signal to the delay locked loop, and an output clock of the delay locked loop; and
storing the waveform, wherein the waveform is determined based on the applying.

11. A computer system, comprising:
a processor;
a memory; and
instructions, residing in the memory and executable by the processor, for top-level testing a delay locked loop to generate a waveform representative of an operation of the delay locked loop, and bottom-level testing a circuit in the delay locked loop dependent on the waveform.

12. The computer system of claim 11, further comprising instructions for:
applying a test value to one selected from the group consisting a reference clock input to the delay locked loop, a reset signal to the delay locked loop, a control voltage of the delay locked loop, a power signal to the delay locked loop, and an output clock of the delay locked loop; and
storing the waveform, wherein the waveform is determined based on the applying.

13. A method for characterizing a delay locked loop, comprising:
step for top-level testing the delay locked loop to generate a waveform representative of an operation of the delay locked loop; and
step for bottom-level testing a circuit in the delay locked loop dependent on the waveform.
